(19) United States
(12) Patent Application Publication
(10) Pub. No.: US 2026/0206193 A1
(43) Pub. Date: Jul. 16, 2026

(54) OPTICAL STORAGE POWER SUPPLY ENCLOSURE

(71) Applicant: SHENZHEN GOSPELL DIGITAL TECHNOLOGY CO., LTD, Shenzhen (CN)

(72) Inventors: Man Yang, Shenzhen (CN); Yongbo Tu, Shenzhen (CN)

(21) Appl. No.: 19/024,185

(22) Filed: Jan. 16, 2025

(51) Int. Cl. H05K 7/20; H05K 5/02; H05K 7/14

(52) U.S. Cl. CPC H05K 7/20909; H05K 5/0217; H05K 7/1427

(57) ABSTRACT

An optical storage power supply enclosure is disclosed, which incorporates the entire heat dissipation device inside, thereby reducing height of the enclosure. Further, electronic heat sources are disposed on side walls or inside of the heat dissipation channel, and inside fan effectively improves heat dissipation efficiency. Waterproof elements are applied between various components such as the upper cover, side plates, side walls and top walls of the two cabins, PCB circuit board, and filter screens, thereby significantly enhancing waterproof performance of the enclosure, e.g., up to IP65 or above. In addition, the air outlet cabin has a higher middle than the two ends to allow water flow downstream. The air intake cabin is vertically arranged and so that air flows from bottom to top, and the fan in a junction of the two cabins, thus further increasing heat dissipation function of the enclosure.

### TECHNICAL FIELD

The disclosure relates to the field of power supply devices, and more particularly to an optical storage power supply enclosure.

### BACKGROUND

In traditional optical storage power products, two or more inductor slots are usually separately fixed under an enclosure, and heat sink with MOS tubes attached is also separately fixed under the enclosure.

As the inductor slots are fixedly installed below the enclosure, height of the entire product is increased. The heat sink with MOS tubes is fixedly installed below the enclosure, which increases volume of the entire products. In additional, the MOS transistor requires a separate heat sink, thus further increasing cost of the products. Moreover, axial fans which are usually disposed outside the enclosure also increase the overall noise of the machine.

### SUMMARY OF THE INVENTION

Therefore, an optical storage power supply enclosure is provided, which can meet the heat dissipation and waterproof requirements, with a smaller overall height.

An optical storage power supply enclosure is provided, which comprises a base and an upper cover covering the base. The base comprises a bottom plate and a plurality of side plates wound around an outer periphery of the bottom plate. The base combined with the upper cover define an approximate closed cavity. The bottom plate is provided with a PCB circuit board, and a plurality of electronic devices are associated to the PCB circuit board. The optical storage power supply enclosure further comprises an air intake cabin and an air outlet cabin, wherein the air intake cabin has an air inlet port and an air forwarding port, the air outlet cabin has at least two exhaust ports located at outer ends of the air outlet cabin and a middle air inlet, the air intake cabin communicates with the air outlet cabin through junction of the air forwarding port and the middle air inlet to allow airflow of the air intake cabin to enter the air outlet cabin and be discharged from the exhaust ports. The electronic devices comprise at least one first electronic device and at least one second electronic device, wherein the first electronic device is disposed on at least one of outer walls of the air intake cabin and the air outlet cabin. The second electronic device is disposed inside the air intake cabin, and at least one of air intake cabin and the air outlet cabin is equipped with a fan inside.

The air intake cabin and the air outlet cabin consists of a heat dissipation channel which is T-shaped in an airflow direction. A T-shaped junction is formed at a communicating point the air intake cabin and the air outlet cabin. The middle air inlet is defined at an middle portion of a lateral face substantially perpendicularly connecting to a forwarding end of the air intake cabin. The air forwarding port is provide at the forwarding end. The air inlet port is disposed at a side plate of the base to inhale cold air from the outside. each exhaust port is disposed at one corresponding side plate of the base. Two exhaust ports are preferably disposed at both ends of the air outlet cabin which are connected to two opposing side plates of the base, and the two exhaust ports are exposed outside of the corresponding side plate of the base. Preferably, a cross-sectional area of air intake cabin is greater than that of the outlet cabin.

The air outlet cabin is preferably in a form with a central portion higher than two sides. For example, the air outlet cabin is in one shape of arc, arch, trapezoid and obtuse angle. The air intake cabin communicates with the air outlet cabin at a lower lateral face of the relatively higher central segment of air outlet cabin.

Preferably, each cabin essentially comprises at least two sidewalls and a top wall. The sidewalls are fixed on the PCB circuit board or the base and form a gas passing cavity in combination with the top wall. The first electronic device is adhered to an outer surface of one sidewall of any of the two cabins, preferably to one or two sidewall of the air outlet cabin, and the second electronic device is located on the PCB circuit board and is covered by any of the two cabins.

Preferably, the upper cover is connected to each side plate of the base by snap fasteners or bolts, and a waterproof sealing ring is provided between the upper cover and the side plates. At least one side plate is equipped with a waterproof joint which is communicated with inside of the cavity defined by the base and the upper cover, and the waterproof joint is configured to connect external cables.

Preferably, the air intake cabin and the air outlet cabin are made of extruded profiles, and the side walls of each cabin are connected to the PCB circuit board or the base by welding, or fixed to the PCB circuit board or the base with bolts. One of a waterproof adhesive and a waterproof sealing gasket is provided between the bottom of each cabin side wall of the two cabins and the PCB circuit board. The junction of the air forwarding port and the middle air inlet is provided with one of a waterproof adhesive and a waterproof sealing gasket. A thermal conductive adhesive is provided to an interface defined between the first electronic device and corresponding cabin.

Preferably, filter screens are respectively installed at the air inlet port and the exhaust ports, and the filter screens are located at the corresponding ends of the two cabin. Waterproof sealing elements are provided between each filter screen and one corresponding end of the two cabins.

Preferably, the fan is disposed at the junction between the two cabins, for forming an air flow channel with a lower gas inlet and left and right exhaust ports. The fan is preferably a centrifugal fan.

Preferably, the first electronic device comprises at least one MOS transistor, and the at least one second electronic device comprises at least one inductor and at least one transformer. The second electronic devices at the same region is potted as an integrate. Preferably, the inductor and the transformer at the same region or side are in sequence arranged inside the air intake cabin and are disposed on the PCB circuit board as a whole with embedment or potting material.

Preferably, the optical storage power supply enclosure further comprises a control electrical box, which is integrally stretched and formed with the upper cover.

Preferably, the air intake cabin is arranged at a vertical direction and the air outlet cabin is arranged at a horizontal direction, for usefully facilitating gas flow from bottom to top.

In the above-mentioned optical storage power supply enclosure, the entire heat dissipation channel formed by the two cabins is provided inside the enclosure, and electronic devices such as MOS tubes, inductors, and transformers that generate a lot of heat are installed inside the enclosure. This greatly reduces overall height of the enclosure. Some electronic devices are further disposed at the side wall of any of the two cabins, thereby achieving both decreased space occupation of the electronic devices and benefit heat dissipation. The second electronic devices are further disposed at inside of the two cabins, accordingly providing a specific sealed heat dissipation channel and a rapid efficient heat dissipation passage, in cooperation with the fan. A plurality of waterproof components is applied to connection between any two parts, for example, between the upper cover and the side walls of the two cabins, between the side plates and any of the two cabins, between the PCB circuit board and the side walls of the two cabins, and between each filter screen and one corresponding end of the two cabins. This provides the entire enclosure with an enhanced waterproof performance. Preferably, the air intake cabin is arranged at a vertical direction and the air outlet cabin is arranged at a horizontal direction. This forms a heat dissipation passage with a lower intake port and two side exhausting ports, for usefully facilitating gas flow. The air outlet cabin is preferably in a form with a central portion higher than two sides, thereby improving waterproof performance. Through placing electronic heat resources on the side walls or inside the heat dissipation channel, and the fan inside the heat dissipation channel also effectively improves the heat dissipation efficiency. As such, due to the above-mentioned construction, the enclosure not only achieves a good heat dissipation function, but also improves the waterproof performance, thereby making the overall protection performance of the enclosure reach IP65 or above. The structure of the present invention is compact, cost-effective, and easy to promote.

### BRIEF DESCRIPTION OF DRAWINGS

FIG. 1 is a schematic perspective view of an optical storage power supply enclosure according to an embodiment of the present invention.

FIG. 2 is a schematic perspective view of inside of the optical storage power supply enclosure with the upper cover removed according to the embodiment of the present invention.

FIG. 3 is another schematic perspective view of inside of the optical storage power supply enclosure with the upper cover and the air intake cabin removed according to the embodiment of the present invention.

FIG. 4 is a schematic perspective view of the air intake cabin and the air outlet cabin of the optical storage power supply enclosure according to the embodiment of the present invention.

FIG. 5 is a schematic structural view of an upper cover of the optical storage power supply enclosure according to the embodiment of the present invention.

### DETAILED DESCRIPTION OF THE INVENTION

The foregoing and other exemplary purposes, aspects and advantages of the present invention will be better understood in principle from the following detailed description of one or more exemplary embodiments of the invention with reference to the embodiment(s) and accompanied drawings. It is understood to one skilled in the art that the following description with reference to the embodiment(s) and accompanied drawings is merely to explain concepts and principals of the present invention but should not be seemed as limitation to the scope of the present invention.

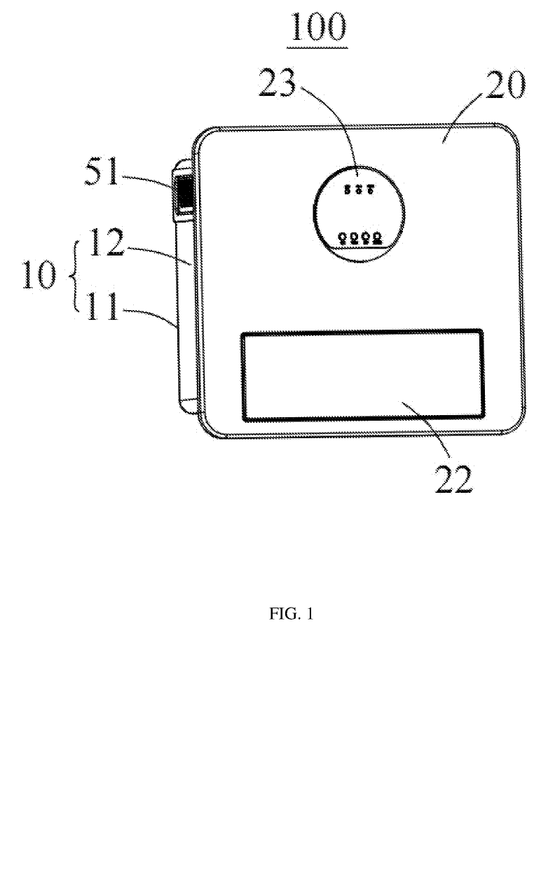

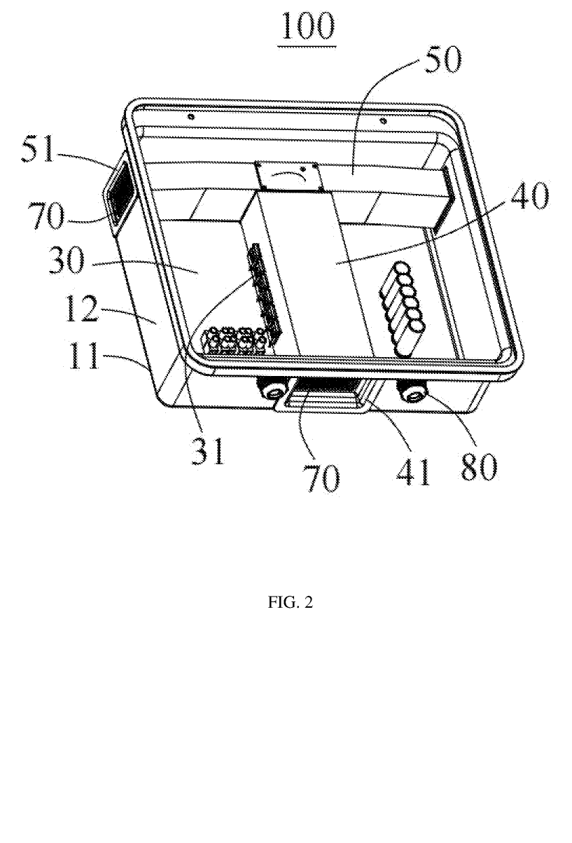

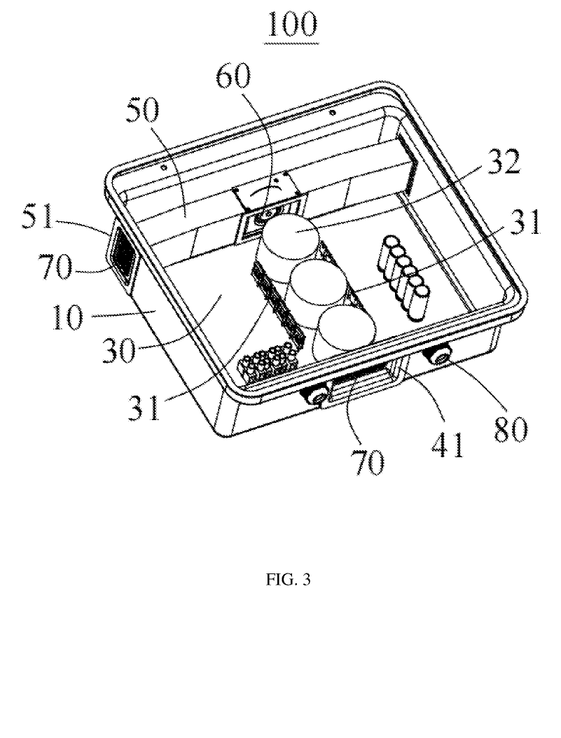

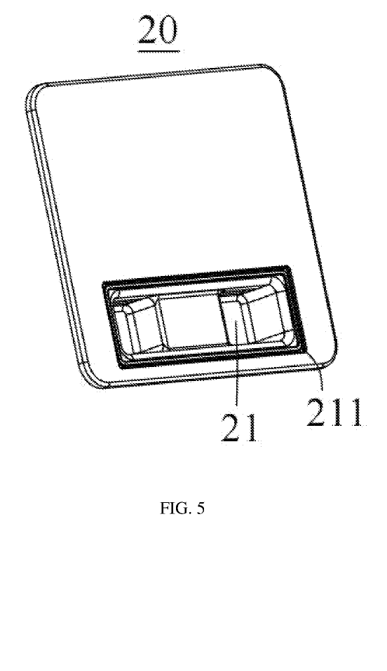

Referring to FIG. 1 through FIG. 5, an optical storage power supply enclosure 100 according to an embodiment of the present invention is illustrated. The optical storage power supply enclosure 100 comprises a base 10 and an upper cover 20 which covers on the base 10. The base 10 comprises a bottom plate 11 and a plurality of side plates 12 wound around an outer periphery of the bottom plate 11. The base 10 combined with the upper cover 20 define an approximate closed cavity. The bottom plate 11 is provided with a PCB circuit board 30, and a plurality of electronic devices are associated to the PCB circuit board 30. The optical storage power supply enclosure 100 further comprises an air intake cabin 40 and an air outlet cabin 50. The air intake cabin 40 has an air inlet port 41 and an air forwarding port, the air outlet cabin 50 has at least two exhaust ports 51 located at outer ends of the air outlet cabin 50 and a middle air inlet. The air intake cabin 40 communicates with the air outlet cabin 50 through a junction of the air forwarding port and the middle air inlet to allow airflow of the air intake cabin 40 to enter the air outlet cabin 50 and be discharged from the exhaust ports 51. The electronic devices include at least one first electronic device 31 and at least one second electronic device 32. The first electronic device 31 is located on at least one of outer walls of the air intake cabin 40 and the air outlet cabin 50. The second electronic device 32 is located inside the air intake cabin 40. At least one of air intake cabin 40 and the air outlet cabin 50 is equipped with a fan 60 inside, for improving air flow inside the heat dissipation channel so as to achieve heat dissipation of the PCB circuit board 30 and electronic devices.

In an embodiment, the air intake cabin 40 is one of a shade, a suction can, an arch-shaped cover and inverted frame-shaped cover plate. The air intake cabin 40 could be, e.g., free of a bottom wall or plate. That is, the air intake cabin 40 without a bottom and a surface region of the PCB circuit board 30 cooperatively with the air intake cabin 40 define a closed cavity as a gas entering passage. Thus, the air intake cabin 40 is free of a bottom which is replaced and closed by one corresponding region of the PCB circuit board 30. In an alternative embodiment, the air intake cabin 40 could be provided with a bottom which is mounted on the PCB circuit board 30. The air intake cabin 40 and the air outlet cabin 50 are preferably an elongated cavity along a gas flow direction. The air outlet cabin 50 is preferably an enclosed elongated cavity or passage.

The air intake cabin 40 and the air outlet cabin 50 consists of a heat dissipation channel which is preferably T-shaped in an airflow direction. A T-shaped junction is formed at a communicating point the air intake cabin 40 and the air outlet cabin 50. The middle air inlet is defined at an middle portion of a lateral face substantially perpendicularly connecting to a forwarding end of the air intake cabin 40. The air forwarding port is provide at the forwarding end. The air inlet port 41 is disposed at a side plate 12 of the base 10 to inhale cold air from the outside. each exhaust port is disposed at one corresponding side plate 12 of the base 10. Two exhaust ports 51 are preferably disposed at both ends of the air outlet cabin 50 which are connected to two opposing side plates 12 of the base 10, and the two exhaust ports 51 are exposed outside of the corresponding side plate 12 of the base 10. Preferably, a cross-sectional area of air intake cabin 40 is greater than that of the outlet cabin, in order to provide an inhaling volume of air intake cabin 40 approximate equivalent to discharging volume of the two exhaust ports 51 of the outlet cabin. More preferably, a cross-sectional area of air intake cabin 40 is about equivalent to 1.5 times or 2 times the cross-sectional area of the air outlet cabin 50.

Preferably, each cabin 40, 50 essentially comprises at least two sidewalls and a top wall. The sidewalls are fixed on the PCB circuit board 30 or the base 10, and form a gas passing cavity in combination with the top wall. The first electronic device 31 is adhered to an outer surface of one sidewall of any of the two cabins 40, 50, preferably to one or two sidewalls of the air outlet cabin 50, and the second electronic device 32 is located on the PCB circuit board 30 and is located inside the heat dissipation channel, e.g., at least most part of the second electronic device 32 extends inside the heat dissipation channel. In another embodiments, the second electronic device 32 is preferably covered by any of the two cabins 40, 50.

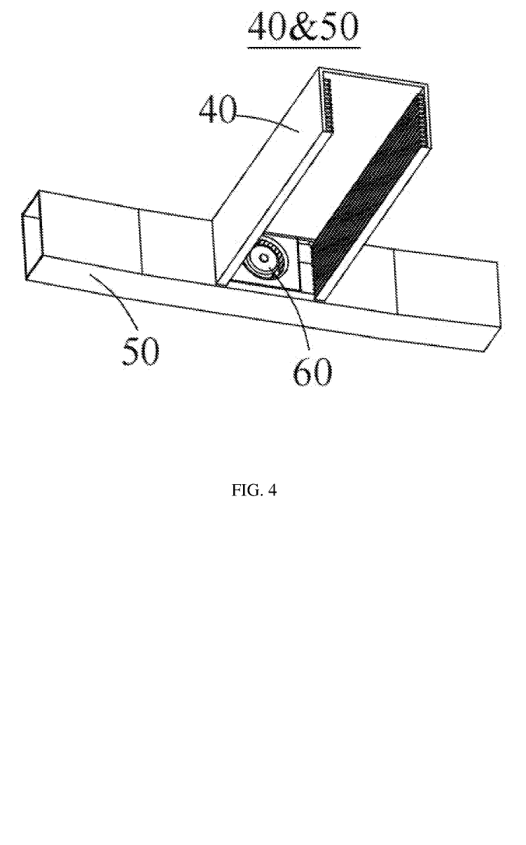

The at least one first electronic device 31 includes two or more devices and are adhered to both side surfaces of the air intake cabin 40, respectively. For example, two or more devices are symmetrically attached to the left and right side surfaces of the air intake cabin 40. As shown in FIG. 4, preferably, inner surfaces of the left and right side walls of the air intake cabin 40 are provided with a plurality of uniformly arranged heat dissipation fins, respectively.

Preferably, the fan 60 is disposed at the junction between the two cabins 40, 50, for forming an air flow channel with a lower gas inlet and left and right exhaust ports 51. The fan 60 is preferably a centrifugal fan 60. Specifically, the centrifugal fan 60 has a large air volume and low noise, which enables the optical storage power supply enclosure 100 to have good heat dissipation effect.

In particular, the optical storage power supply enclosure 100 could be, e.g., fixed onto a wall in use. Preferably, the air intake cabin 40 is arranged at a vertical direction and the air outlet cabin 50 is arranged at a horizontal direction and is positioned a top of the air intake cabin 40, for usefully facilitating gas flow. The air inlet port 41 is usefully disposed at a bottom side plate 12. The two exhaust ports 51 are respectively disposed at two side plates 12 adjacent to the bottom side plate 12.

The air outlet cabin 50 is preferably in a form with a central portion higher than two sides. For example, the air outlet cabin 50 is in one shape of arc, arch, trapezoid and obtuse angle. Namely, the air outlet cabin 50 slopes from the middle to both sides or both ends. Further, two side walls of the air outlet cabin 50 slopes from the middle to both sides or both ends to facilitate water flow out of the cabin. According to using direction, the two side walls of the air outlet cabin 50 are referred to as an upper wall and a lower wall, and a surface of the top wall of the air outlet cabin 50 parallel to a vertical plane. In other words, the exhausting ports is lower than the middle port with reference to an installing direction. Namely, airflow direction in the combined heat dissipation channel by the two cabins 40, 50 is from bottom to top. In this way, water is prevented from entering the air intake cabin 40 through the air outlet cabin 50, so that the heat dissipation channel has a good waterproof performance. Further, the two side walls of the air outlet cabin 50 with a central portion higher than two sides allows condensed water flow to both sides along an inner surface thereof. The air intake cabin 40 communicates with the air outlet cabin 50 at a lower side wall of the relatively higher central segment of air outlet cabin 50.

Preferably, the upper cover 20 is connected to each side plate 12 of the base 10 by snap fasteners or bolts, and a waterproof sealing ring is provided between the upper cover 20 and the side plates 12. At least one side plate 12 is equipped with a waterproof joint 80 which is communicated with inside of the cavity, and the waterproof joint 80 is configured to connect external cables.

Specifically, the waterproof joint 80 and the air inlet port 41 are both disposed on the bottom side panel of the base 10. As such, the waterproof joint 80 and the air inlet port 41 face downward to prevent water from entering the enclosure 100 through the waterproof joint 80 or the air inlet.

Specifically, the air outlet cabin 50 has four interconnected side walls, and the walls of the air outlet cabin 50 does not come into contact with the PCB circuit board 30, for preventing water entering through the exhausting ports of the air outlet cabin 50 from coming into contact with the PCB circuit board 30.

Preferably, the air intake cabin 40 and the air outlet cabin 50 are made of extruded profiles, and the side walls of each cabin are connected to the PCB circuit board 30 or the base 10 by welding, or fixed to the PCB circuit board 30 or the base 10 with bolts. One of a waterproof adhesive and a waterproof sealing gasket is provided between the bottom of each cabin side wall of the two cabins 40, 50 and the PCB circuit board 30. Partial embedment adhesive is applied between the air intake cabin 40 and the air outlet cabin 50 and the PCB circuit board 30, which improves protective performance of the PCB circuit board 30. The air outlet cabin 50 further comprises a bottom wall so that interior of the whole air outlet cabin 50 is fully isolated from the PCB circuit board 30 to prevent water from seeping onto the PCB circuit board 30. The junction of the air forwarding port and the middle air inlet is provided with one of a waterproof adhesive and a waterproof sealing gasket. A thermal conductive adhesive is provided to an interface defined between the first electronic device 31 and corresponding cabin.

Specifically, the heat dissipation channel divides the PCB circuit board 30 into multiple areas, and waterproof embedment glue is applied between each area to ensure that they have the same level of protection.

Further, the air intake cabin 40 and the air outlet cabin 50 are made of extruded profiles that are integrally formed. The bottom plate 11 and each side plate 12 of the base 10 are integrally stretched and formed, which can improve the waterproof performance of the enclosure 100.

Preferably, filter screens 70 are respectively installed at the air inlet port 41 and the exhaust ports 51, and the filter screens 70 could be, e.g., located at the corresponding ends of the two cabins 40, 50. Waterproof sealing elements are provided between each filter screen 70 and one corresponding end or port of the two cabins 40, 50. For example, waterproof sealing rings are provided at interfaces between the end of the heat dissipation channel, the side plates 12, and the filter screens 70.

Preferably, the first electronic device 31 comprises at least one MOS transistor, and the at least one second electronic device 32 comprises at least one inductor and at least one transformer. Preferably, the inductor and the transformer at the same region or side are in sequence arranged inside the air intake cabin 40 and are disposed on the PCB circuit board 30 as a whole with embedment or potting material.

In operation, both the first electronic devices 31 and the second electronic devices 32 are electronic devices that generate a large amount of heat. By placing these electronic devices on the side walls or inside of any of the cabins 40, 50, heat generated by the electronic devices can be quickly dissipated, thereby achieving good heat dissipation effect.

Preferably, the optical storage power supply enclosure 100 further comprises a control electrical box (not shown), which is integrally stretched and formed with the upper cover 20. The lower half of the upper cover 20 has a concave groove 21, and the control electrical box is disposed inside the concave groove 21. The groove 21 is integrally stretched and formed with the upper cover 20. The control electrical box is used for wiring the PCB circuit board 30 with external cables.

Preferably, a top cover 22 is provided on the groove 21, and area of the top cover 22 is larger than that of a top surface of the groove 21. The top cover 22 covers the groove 21 and is flush with an outer surface of the upper cover 20. A waterproof ring is provided between the top cover 22 and surrounding side walls of the groove 21. At least one drainage hole 211 is provided at the connection edge between a top surface of the surrounding side walls of the groove 21 and the upper cover 20. The drainage hole 211 is used to discharge water droplets from gap between the upper cover 20 and the top cover 22.

Specifically, the control electrical box is installed in the groove 21 of the upper cover 20. When wiring, the top cover 22 of the control electrical box can be opened to perform the wiring operation without opening the upper cover 20 of the optical storage power supply enclosure 100. The cables enter interior of the optical storage power supply enclosure 100 through the waterproof joint 80, thereby improving protective performance of the optical storage power supply enclosure 100.

Furthermore, the upper cover 20 is provided with a control panel 23, which is equipped with touch buttons and status display lights. The control panel 23 is used to control normal operation of the devices inside the optical storage power supply enclosure 100.

The above-mentioned optical storage power supply enclosure 100 is configured for a photovoltaic devices and is usually used in outdoor circumstance. In the above-mentioned optical storage power supply enclosure 100, the entire heat dissipation channel formed by the two cabins 40, 50 is provided inside the enclosure 100, and electronic devices such as MOS tubes, inductors, and transformers that generate a lot of heat are installed inside the enclosure 100. This greatly reduces overall height of the enclosure 100. Some electronic devices are further disposed at the side wall of any of the two cabins 40, 50, thereby achieving both decreased space occupation of the electronic devices and benefit heat dissipation. The second electronic devices 32 are further disposed at inside of the two cabins 40, 50, accordingly providing a specific sealed heat dissipation channel and a rapid efficient heat dissipation passage, in cooperation with the fan 60. A plurality of waterproof components is applied to connection between any two parts, for example, between the upper cover 20 and the side walls of the two cabins 40, 50, between the side plates 12 and any of the two cabins 40, 50, between the PCB circuit board 30 and the side walls of the two cabins 40, 50, and between each filter screen 70 and one corresponding end of the two cabins 40, 50. This provides the entire enclosure 100 with an enhanced waterproof performance. Preferably, the air intake cabin 40 is arranged at a vertical direction and the air outlet cabin 50 is arranged at a horizontal direction. This forms a heat dissipation passage with a lower intake port and two side exhausting ports, for usefully facilitating gas flow. The air outlet cabin 50 is preferably in a form with a central portion higher than two sides, thereby improving waterproof performance. Through placing electronic heat resources on the side walls or inside the heat dissipation channel, and the fan 60 inside the heat dissipation channel also effectively improves the heat dissipation efficiency. As such, due to the above-mentioned construction, the enclosure 100 not only achieves a good heat dissipation function, but also improves the waterproof performance, thereby making the overall protection performance of the enclosure 100 reach IP65 or above. The structure of the present invention is compact, cost-effective, and easy to promote.

The above is only a preferred embodiment of the disclosure and does not impose any formal limitations on it. Therefore, any simple modifications, equivalent changes, and modifications made to the above embodiments base 10d on the technical essence of the disclosure, which are not separated from the technical solution of the disclosure, shall fall within the scope of protection of the technical solution of the disclosure.

What is claimed is:

1. An optical storage power supply enclosure, comprising a base and an upper cover covering the base, the base comprising a bottom plate and a plurality of side plates wound around an outer periphery of the bottom plate, the base combined with the upper cover defining an approximate closed cavity, the bottom plate being provided with a PCB circuit board, and a plurality of electronic devices being associated to the PCB circuit board, wherein the optical storage power supply enclosure further comprises an air intake cabin and an air outlet cabin;
the air intake cabin has an air inlet port and an air forwarding port;
the air outlet cabin has at least two exhaust ports located at outer ends of the air outlet cabin and a middle air inlet;
the air intake cabin communicates with the air outlet cabin through junction of the air forwarding port and the middle air inlet to allow airflow of the air intake cabin to enter the air outlet cabin and be discharged from the exhaust ports;
the electronic devices comprise at least one first electronic device and at least one second electronic device, wherein the first electronic device is disposed on at least one of outer walls of the air intake cabin and the air outlet cabin, the second electronic device is disposed inside the air intake cabin, and at least one of air intake cabin and the air outlet cabin is equipped with a fan inside.

2. The optical storage power supply enclosure according to claim 1, wherein the air intake cabin and the air outlet cabin consists of a heat dissipation channel which is T-shaped in an airflow direction, a T-shaped junction is formed at a communicating point the air intake cabin and the air outlet cabin, the middle air inlet is defined at an middle portion of a lateral face substantially perpendicularly connecting to a forwarding end of the air intake cabin, and the air forwarding port is provide at the forwarding end.

3. The optical storage power supply enclosure according to claim 1, wherein the air inlet port is disposed at a side plate of the base to inhale cold air from the outside, each exhaust port is disposed at one corresponding side plate of the base, two exhaust ports are preferably disposed at both ends of the air outlet cabin which are connected to two opposing side plates of the base, and the two exhaust ports are exposed outside of the corresponding side plate of the base, a cross-sectional area of air intake cabin is about equivalent to 1.5 times or 2 times the cross-sectional area of the outlet cabin.

4. The optical storage power supply enclosure according to claim 1, wherein the air outlet cabin is in a form with a central portion higher than two sides.

5. The optical storage power supply enclosure according to claim 1, wherein the air outlet cabin is in one shape of any of arc, arch, trapezoid and obtuse angle; the air outlet cabin slopes from the middle to both sides or both ends; two side walls of the air outlet cabin slopes from the middle to both sides or both ends to facilitate water flow out of the cabin; and the exhausting ports is lower than the middle port with reference to an installing direction so that airflow direction in the combined heat dissipation channel by the two cabins is from bottom to top.

6. The optical storage power supply enclosure according to claim 1, wherein the air intake cabin communicates with the air outlet cabin at a lower lateral face of a relatively higher central segment of air outlet cabin than two end of air outlet cabin.

7. The optical storage power supply enclosure according to claim 1, wherein each cabin essentially comprises two sidewalls fixed on the PCB circuit board or the base and a top wall for defining a gas passing cavity in combination with the sidewalls, the first electronic device is attached to one sidewall of any of the two cabins, and the second electronic device is mounted on the PCB circuit board and is covered by any of the two cabins.

8. The optical storage power supply enclosure according to claim 1, wherein the upper cover is connected to each side plate of the base by snap fasteners or bolts; a waterproof sealing ring is provided between the upper cover and the side plates; at least one side plate is equipped with a waterproof joint which is communicated with inside of the cavity; and the waterproof joint is configured to connect external cables.

9. The optical storage power supply enclosure according to claim 7, wherein the air intake cabin and the air outlet cabin are made of extruded profiles; the side walls of each cabin are connected to the PCB circuit board by welding or fixed to the PCB circuit board or the base with bolts.

10. The optical storage power supply enclosure according to claim 7, wherein the air outlet cabin further comprises a bottom wall so that interior of the whole air outlet cabin is fully isolated from the circuit board to prevent water from seeping onto the circuit board; the air intake cabin is free of a bottom which is replaced and closed by one corresponding region of the PCB circuit board.

11. The optical storage power supply enclosure according to claim 1, wherein one of a waterproof adhesive and a waterproof sealing gasket is provided between the bottom of each cabin side wall of the two cabins and the PCB circuit board, the junction of the air forwarding port and the middle air inlet is provided with one of a waterproof adhesive and a waterproof sealing gasket, and a thermal conductive adhesive is provided to an interface defined between the first electronic device and corresponding cabin.

12. The optical storage power supply enclosure according to claim 1, wherein filter screens are respectively installed at the air inlet port and the exhaust ports, and the filter screens are located at the corresponding ends of the two cabin; and waterproof sealing elements are provided between each filter screen and one corresponding end of the two cabins.

13. The optical storage power supply enclosure according to claim 1, wherein the fan is disposed at the junction between the two cabins, for forming an air flow channel with a lower gas inlet and left and right exhaust ports, and the fan is a centrifugal fan.

14. The optical storage power supply enclosure according to claim 1, wherein the first electronic device comprises at least one MOS transistor; the at least one second electronic device comprises at least one inductor and at least one transformer.

15. The optical storage power supply enclosure according to claim 14, wherein the inductor and the transformer at the same region are in sequence arranged inside the air intake cabin and are disposed on the PCB circuit board as a whole with embedment or potting material.

16. The optical storage power supply enclosure according to claim 1, wherein the optical storage power supply enclosure further comprises a control electrical box, which is integrally stretched and formed with the upper cover.

17. The optical storage power supply enclosure according to claim 16, wherein a lower half of the upper cover has a concave lower groove, and the control electrical box is disposed inside the lower groove; and the lower groove is integrally stretched and formed with the upper cover.

18. The optical storage power supply enclosure according to claim 17, wherein a top cover is provided on the lower groove, and area of the top cover is larger than that of a top surface of the lower groove; the top cover covers the lower groove and is flush with an outer surface of the upper cover; a waterproof ring is provided between the top cover and side walls of the lower groove; and at least one drainage hole is provided at the connection edge between a top surface of the surrounding side walls of the lower groove and the upper cover to discharge water droplets from gap between the upper cover and the top cover.

19. The optical storage power supply enclosure according to claim 1, wherein the air intake cabin is arranged at a vertical direction and the air outlet cabin is arranged at a horizontal direction, for usefully facilitating gas flow from bottom to top.

20. The optical storage power supply enclosure according to claim 1, wherein inner surfaces of the side walls of the air intake cabin are provided with a plurality of uniformly arranged heat dissipation fins, respectively.
